(19) United States
(12) Patent Application Publication
(10) Pub. No.: US 2017/0052014 A1
(43) Pub. Date: Feb. 23, 2017

(54) METHOD, APPARATUS, AND SYSTEM FOR PASSIVE DIE STRAIN MEASUREMENT

(71) Applicant: GLOBALFOUNRIES Inc., Grand Cayman (KY)

(72) Inventor: RYAN SCOTT SMITH, Clifton Park, NY (US)

(73) Assignee: GLOBALFOUNDRIES INC., GRAND CAYMAN (KY)

(21) Appl. No.: 14/830,214

(22) Filed: Aug. 19, 2015

(51) Int. Cl. G01B 7/14; G01L 1/00; H01L 21/67; G01N 27/02; H01L 21/66; H01L 23/64

(52) U.S. Cl. CPC G01B 7/14; H01L 22/32; H01L 23/642; H01L 23/645; H01L 21/67288; H01L 22/12; G01N 27/028; G01L 1/005; G01B 2210/56

(57) ABSTRACT

At least one method, apparatus, and system for determining a distance between layers of a semiconductor device and, if desired, modifying a semiconductor device manufacturing process in view of the determined distance. The system comprises and the methods make use of a test circuit comprising a resistor, at least one of an inductor and a capacitor, a first terminal and a second terminal each configured to electrically connect to a first layer circuit and a second layer circuit of a semiconductor device.

### BACKGROUND OF THE INVENTION

Field of the Invention

Generally, the present disclosure relates to the manufacture of sophisticated semiconductor devices, and, more specifically, to various methods and structures for passively measuring semiconductor device strain, for improved conformance of produced semiconductor devices to specifications and improved monitoring of manufacturing processes.

Description of the Related Art

The manufacture of semiconductor devices requires a number of discrete process steps to create a packaged semiconductor device from raw semiconductor material. The various processes, from the initial growth of the semiconductor material, the slicing of the semiconductor crystal into individual wafers, the fabrication stages (etching, doping, ion implanting, or the like), to the packaging and final testing of the completed device, are so different from one another and specialized that the processes may be performed in different manufacturing locations that contain different control schemes.

Generally, a set of processing steps is performed on a group of semiconductor wafers, sometimes referred to as a lot, using semiconductor-manufacturing tools, such as exposure tool or a stepper. As an example, an etch process may be performed on the semiconductor wafers to shape objects on the semiconductor wafer, such as polysilicon lines, each of which may function as a gate electrode for a transistor. As another example, a plurality of metal lines, e.g., aluminum or copper, may be formed that serve as conductive lines that connect one conductive region on the semiconductor wafer to another. In this manner, integrated circuit chips may be fabricated.

Today's semiconductor device manufacturing processes may call for precise placement of one or more layers relative to one another, thereby requiring measurement of distances between layers. Such distances may be measured by techniques sensitive to stress and/or strain. The art has reported the use of Wheatstone bridges and MIM caps for the purpose of measuring distances between layers. However, Wheatstone bridges and MIM caps have several shortcomings that render them undesirable for use in semiconductor device manufacturing processes. First, to fabricate Wheatstone bridges and/or MIM caps in a semiconductor device generally requires processing steps different from those described above. Therefore, fabricating Wheatstone bridges and/or MIM caps renders semiconductor device manufacture more time consuming and more resource intensive. Second, Wheatstone bridges and/or MIM caps generally may only be placed at the uppermost levels of a semiconductor device stack. They are, therefore, unsuitable for measuring distances between deeper layers in a semiconductor device stack.

Therefore, it would be desirable to have a stress sensing system that can be readily fabricated and that can be placed between any two layers of a semiconductor device stack. The present disclosure may address and/or at least reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods, apparatus and systems for determining a distance between layers of a semiconductor device and, if desired, modifying a semiconductor device manufacturing process in view of the determined distance. The system comprises and the methods make use of a test circuit comprising a resistor, at least one of an inductor and a capacitor, a first terminal and a second terminal each configured to electrically connect to a first layer circuit and a second layer circuit of a semiconductor device.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a stylized depiction of a stress sensing system 110 and its accompanying inputs and outputs in accordance with embodiments herein;

FIG. 2 illustrates a stylized depiction of particular components of the stress sensing system 110 in more detail in accordance with embodiments herein;

FIG. 3A illustrates a stylized, simplified depiction of a test circuit 210 in accordance with embodiments herein;

FIG. 3B illustrates a stylized, simplified depiction of a test circuit 210A in accordance with embodiments herein;

FIG. 3C illustrates a stylized, simplified depiction of a test circuit 210B in accordance with embodiments herein;

FIG. 3D illustrates a stylized, simplified depiction of a test circuit 210C in accordance with embodiments herein;

FIG. 4 illustrates a stylized depiction of a model for determining a distance between layers 410 and 420 of a semiconductor device in accordance with embodiments herein;

FIG. 5 illustrates the ratio Vₒᵤₜ/Vᵢₙ as a function of internal resistance of an inductor 320 of a test circuit 210 in accordance with embodiments herein;

FIG. 6 illustrates a semiconductor device manufacturing system for manufacturing a device with reference to interlayer distances determined by stress sensing system 110 in accordance with embodiments herein;

FIG. 7 illustrates a stylized, simplified depiction of a semiconductor device 615 comprising a test circuit 210 in accordance with embodiments herein;

FIG. 8 illustrates a stylized, simplified depiction of a semiconductor device 615 comprising a test circuit 210 in accordance with embodiments herein;

FIG. 9 illustrates a stylized, simplified depiction of a semiconductor device 615 comprising features 920 and a test circuit 210 in accordance with embodiments herein; and

FIG. 10 illustrates a flowchart of a method 1000 in accordance with embodiments herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide for measuring strain between two layers of a semiconductor wafer stack, such as a back-end-of-line (BEOL) stack, using a test circuit smaller and more easily fabricated than devices previously known in the art. The test circuit of embodiments herein is capable of providing an output indicative of the strain between at least two layer of the stack. In some embodiments herein, a distance between two layers of the stack may be determined, with such distance being related to the strain between the two layers.

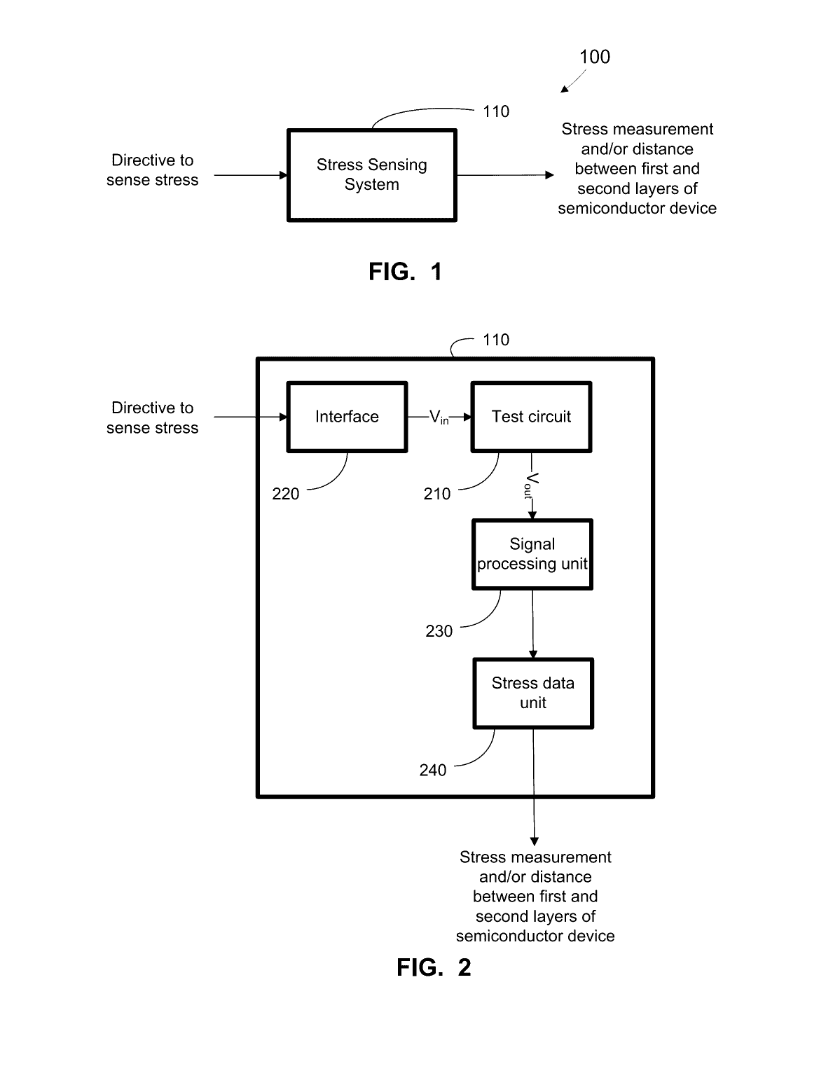

Turning now to FIG. 1, a stylized block diagram depicts one embodiment of a system 100, comprising a stress sensing system 110. The stress sensing system 110 may be configured to receive a directive to sense stress between first and second layers of a semiconductor device. Upon receipt of the directive, the stress sensing system 110 may perform various operations described below. The stress sensing system 110 may be configured to provide an output comprising a stress measurement between two layers of a wafer stack and/or a distance between first and second layers of a semiconductor device, which may be used to determine a stress indication between the first and second layers.

FIG. 2 depicts a more detailed, stylized block diagram of one embodiment of the stress sensing system 110 in accordance with embodiments herein. The stress sensing system 110 may comprise an interface 220 configured to receive the directive to sense stress. In one embodiment, the directive may be an electronic signal directing the initiation of a stress measurement process. In responsive to the directive, the interface 220 may be further configured to deliver an input voltage (V) to an input terminal of a test circuit 210.

The stress sensing system 110 may also comprise a test circuit 210. The test circuit 210 may comprise a voltage input configured to receive Vᵢₙ from the interface 220. The test circuit 210 may also comprise a voltage output configured to deliver an output voltage (Vₒᵤₜ) to a signal processing unit 230. The signal processing unit 230 may be capable of processing the output voltage, wherein the processing may include performing a analog-to-digital (A/D) conversion (using an A/D converter) and/or performing various digital signal processing (DSP) operations upon the output voltage. The processed signal is then sent to the stress data unit 240, which is capable of determining an indication of stress (e.g., the distance between two wafers in a stack) and/or the actual stress measurement between two layers of a wafer stack.

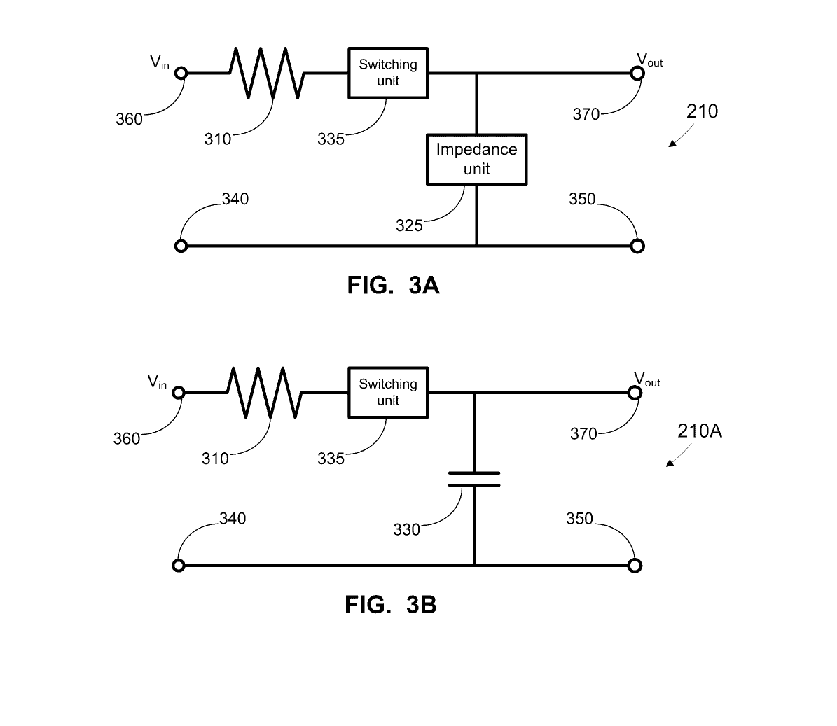

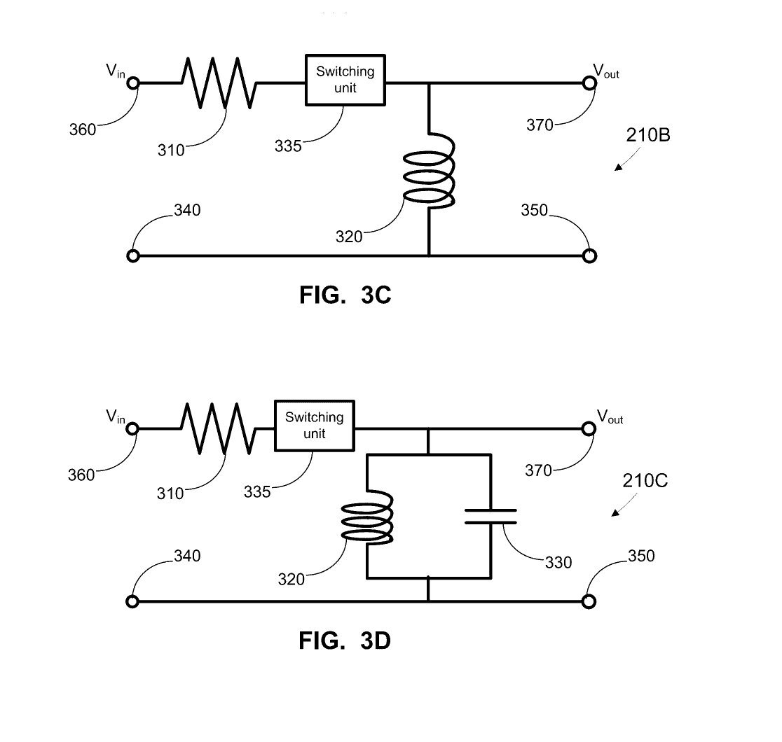

FIG. 3A illustrates a stylized diagram of a the test circuit 210 of FIG. 2, in accordance with embodiments herein. The test circuit 210 comprises a resistor 310, which is in series with an impedance unit 325. The impedance unit 325 may comprise passive and/or active components that are capable of providing a predetermined impedance. For example, as illustrated below, the impedance unit 325 may comprise capacitors, inductors, and/or solid state device that provide an impedance.

The test circuit 210 may also comprise a switching unit 335 in series with the resistor 310. The switching unit 335 may comprise a switch that is capable of opening the circuit of the resistor 310 in series with the impedance unit 325. In this manner, the operation of the test circuit 210 may be activated or terminated by the controlling the switching unit 335. That is, by closing the switch(es) in switching unit 335, the test circuit 210 may be activated, and conversely, by opening the switch(es) in switching unit 335, the test circuit 210 may be deactivated.

FIGS. 3B-3D present various embodiments of the test circuit 210 in more detail. FIG. 3B depicts a test circuit 210A that comprises a capacitance impedance. The test circuit 210A comprises a resistor 310, which is in series with a capacitor 330. The resistor 310 may have any resistance which the person of ordinary skill in the art, having the benefit of the present disclosure, may understand to be usable and convenient to implement in carrying out the present invention. In one particular embodiment, the resistor 310 may have a resistance from about 50Ω to about 250Ω.

Similarly, the capacitor 330 may have any capacitance which the person of ordinary skill in the art, having the benefit of the present disclosure, may understand to be usable and convenient to implement in carrying out the present invention. The capacitance will depend on the area of the capacitor plates, among other considerations. In one embodiment, the capacitor 330 may have plates with an area of about 30 μm×30 μm (900 μm²). Together, the resistor 310 and the capacitor 330 form an RC circuit.

Test circuit 210A also comprises a voltage input node 360, wherein the voltage input node 360 is electrically connected to the resistor 310. The voltage input node 360 is configured to receive Vᵢₙ. The test circuit 210A also comprises a voltage output node 370. The voltage output node 370 is configured to deliver Vₒᵤₜ of the test circuit 210 to other elements of stress sensing system 110, as depicted in FIG. 2 and described hereinafter.

In addition to voltage input node 360 and voltage output node 370, test circuit 210A may comprise two additional terminals. A first terminal 340 may be configured to be electrically connected to a first layer circuit in a first layer of a semiconductor device, and a second terminal 350 may be configured to be electrically connected to a second layer circuit in a second layer of a semiconductor device. The response provided by the RC circuit in the output node 370 may be indicative of the distance between two layers of a wafer stack.

FIG. 3C depicts a test circuit 210B. The test circuit 210B contains numerous elements in common with test circuit 210A, and such common elements need not be described again. Test circuit 210B comprises an inductor 320 in series with the resistor 310. The inductor 320 may have any inductance which the person of ordinary skill in the art, having the benefit of the present disclosure, may understand to be usable and convenient to implement in carrying out the present invention. The inductance may depend on the metal width and radius of the inductor 320. In one particular embodiment, the inductor 320 may have a metal width equal to or less than about 500 nm. In one embodiment, the inductor 320 may have a radius of 10 μm. In one particular embodiment, the inductor 320 may have an internal resistance from about 50Ω to about 250Ω. Together, the resistor 310 and the inductor 320 form an RL circuit. The response provided by the RL circuit in the output node 370 may be indicative of the distance between two layer of a wafer stack.

FIG. 3D depicts a test circuit 210C. Each depicted element of test circuit 210C is also an element of at least one of test circuits 210A-210B. For example, test circuit 210C comprises an inductor 320 and a capacitor 330, as described above, in parallel with each other, wherein both are in series with the resistor 310. Together, the resistor 310 and the inductor-capacitor combination form an RLC circuit. The response provided by the RCL circuit in the output node 370 may be indicative of the distance between two layer of a wafer stack.

Any one of test circuits 210A-210C may be used according to the present invention. In one embodiment, two or more of test circuits 210A-210C may be used according to the present invention. Further, each of the test circuits 210A-210C used according to the present invention may be used multiple times in various locations within a semiconductor device.

In one particular embodiment of the present invention, test circuit 210 comprises a resistor 310, an inductor 320, and a capacitor 330, wherein the resistor 310 is in series with the inductor 320 and the capacitor 330, and the inductor 320 and the capacitor 330 are in parallel. The test circuit 210 of this embodiment further comprises a first terminal 340 electrically connected to a first layer circuit in a first layer of a semiconductor device (not shown in FIGS. 1-3D), wherein the first terminal 340 is in series with the inductor 320 and the capacitor 330. Also, the test circuit 210 of this embodiment further comprises a second terminal 350 electrically connected to a second layer circuit in a second layer of the semiconductor device (not shown in FIGS. 1-3D), wherein the second terminal 350 is in series with the inductor 320 and the capacitor 330. The test circuit 210 of this embodiment also comprises a voltage input node 360 electrically connected to the resistor 310. In addition, the test circuit 210 of this embodiment also comprises a voltage output node 370.

Returning to FIG. 2, in the depicted embodiment, test circuit 210 delivers Vₒᵤₜ to a signal processing unit 230. The signal processing unit 230 may perform one or more signal processing functions, including, but not limited to, sampling, amplifying, smoothing, or analog-to-digital converting, among others, which may be performed by one or more known electrical signal processing devices, e.g., amplifiers, analog-to-digital converters, or the like. Such processing may render the Vₒᵤₜ signal delivered by test circuit 210 more suitable for performing distance measurements between first and second semiconductor device layers. As should be apparent to those skilled in the art, the signal processing unit 230 may be omitted from stress sensing system 110.

After signal processing, if any, is performed by signal processing unit 230 (if this unit is included in stress sensing system 110), the Vₒᵤₜ signal is delivered to a stress data unit 240. The stress data unit 240 may be configured to receive Vₒᵤₜ from the voltage output of the test circuit 210 (either directly from test circuit 210 or indirectly via signal processing unit 230) and determine a distance between the first layer and the second layer of the semiconductor device, based on Vₒᵤₜ and Vᵢₙ.

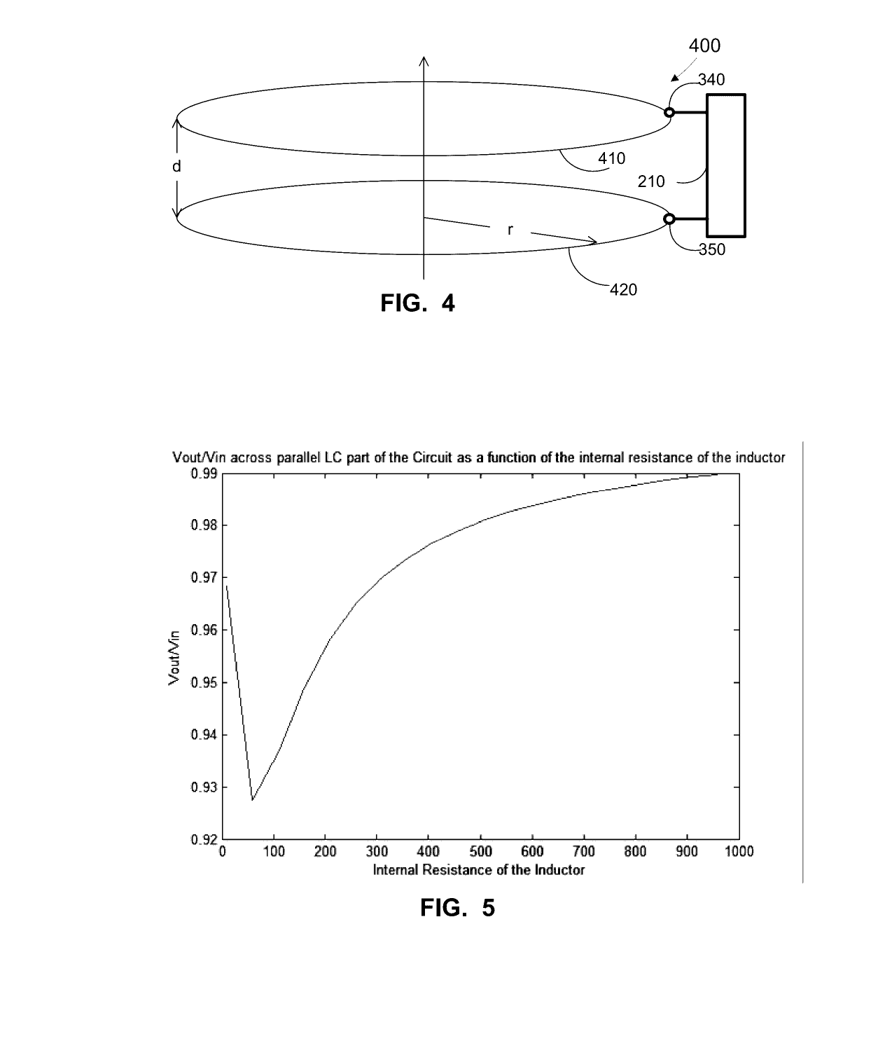

One embodiment by which stress data unit 240 may determine a distance between the first layer and the second layer of the semiconductor device is as follows, with reference to FIG. 4. FIG. 4 conceptually depicts a model 400 comprising two current loops, a first layer circuit 410 in a first layer of a semiconductor device and a second layer circuit 420 in a second layer of the semiconductor device, in accordance with embodiments herein. Each of the first layer circuit 410 and the second layer circuit 420 are modeled as circles with a radius r, and the first layer and the second layer are separated by a distance d. A test circuit 210 as shown in FIG. 3A, comprising first terminal 340 and second terminal 350, is electrically connected to the first layer circuit 410 and the second layer circuit 420.

By Ampere's Law, in embodiments wherein impedance unit 325 comprises an inductor 320, the inductance L across inductor 320 of test circuit 210 may be approximated as

$$L = \frac{4 {πμ}_{0} {r}^{2}}{d} ,$$

wherein μ₀ is the magnetic constant. In embodiments wherein impedance unit 325 comprises a capacitor 330, the capacitance C across capacitor 330 of test circuit 210C is given by

$$C = {ε}_{0} \frac{A}{d} ,$$

wherein A is the area of each of the capacitor plates and ε₀ is the electric constant. The values of L and C may then be used to determine

$${V}_{out} / {V}_{in} , by {V}_{out} / {V}_{in} = \frac{ω L}{{[ {{R}^{2} ( 1 - {ω}^{2} LC )}^{2} + {ω}^{2} {L}^{2} ]}^{1 / 2}} .$$

Therefore, if Vᵢₙ is held at a fixed value, Vₒᵤₜ provided by the test circuit 210 may be determined.

For typical values of r (20 μm), A (900 μm²), and d (60 nm), if test circuit 210 is driven at 100 MHz, a 5 Å (0.5 nm) change in the distance between the first layer and the second layer will yield about a 0.3% change in Vₒᵤₜ from test circuit 210.

Although FIG. 4 has been described with reference to test circuit 210 of FIG. 3A, other test circuits, e.g., test circuit 210A, test circuit 210B, or test circuit 210C, may be used.

As stated above, the resistor 310 may have any desired resistance. FIG. 5 shows Vₒᵤₜ/Vᵢₙ as a function of the internal resistance of the inductor. As indicated, the correlation between Vₒᵤₜ and Vᵢₙ increases, i.e., their values merge when the internal resistance of impedance unit 325 increases above about 80 Ohms. Also as indicated in FIG. 5, as the internal resistance decreases down to about 80 Ohms, the correlation between Vₒᵤₜ and Vᵢₙ also decreases.

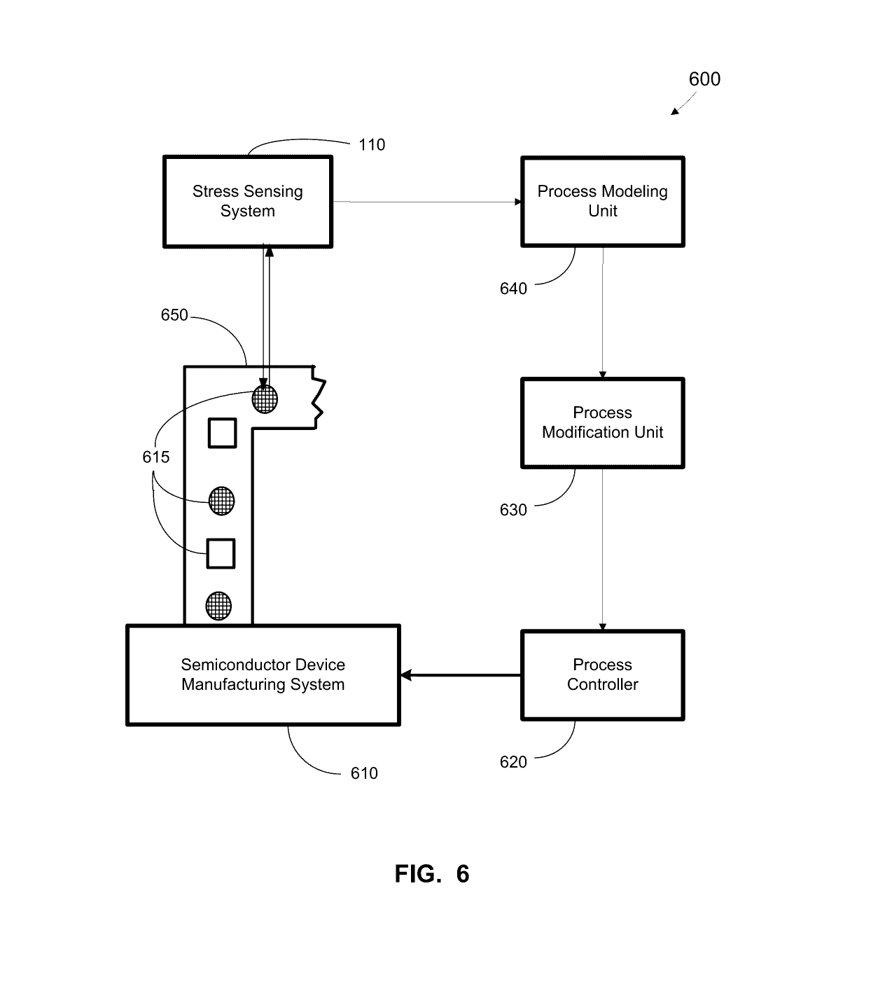

Turning now to FIG. 6, a stylized depiction of a system for fabricating a semiconductor device package comprising a stress sensing system 110, in accordance with embodiments herein, is illustrated. The system 600 of FIG. 6 may comprise a semiconductor device manufacturing system 610 and a process controller 620. The semiconductor device manufacturing system 610 may manufacture semiconductor devices based upon one or more instruction sets provided by the process controller 620, wherein an instruction set comprises a plurality of parameters for manufacture of the semiconductor device. The process controller 620 may also be configured to provide one or more modified instruction sets, as may be generated by the process modification unit 630 described hereinafter, for manufacture of subsequent iterations of the semiconductor device.

The semiconductor device manufacturing system 610 may comprise various processing stations, such as etch process stations, photolithography process stations, CMP process stations, etc. One or more of the processing steps performed by the semiconductor device manufacturing system 610 may be controlled by the process controller 620. The process controller 620 may be a workstation computer, a desktop computer, a laptop computer, a tablet computer, or any other type of computing device comprising one or more software products that are capable of controlling processes, receiving process feedback, receiving test results data, performing learning cycle adjustments, performing process adjustments, etc.

The semiconductor device manufacturing system 610 may produce semiconductor devices (e.g., integrated circuits) on a medium, such as silicon wafers. The semiconductor device manufacturing system 610 may provide processed semiconductor devices 615 on a transport mechanism 650, such as a conveyor system. In some embodiments, the conveyor system may be sophisticated clean room transport systems that are capable of transporting semiconductor wafers. In one embodiment, the semiconductor device manufacturing system 610 may comprise a plurality of processing steps, e.g., the 1^{st} process step, the 2^{nd} process set, etc.

In some embodiments, the items labeled “615” may represent individual wafers, and in other embodiments, the items 615 may represent a group of semiconductor wafers, e.g., a “lot” of semiconductor wafers. The semiconductor device 615 may comprise one or more of a transistor, a capacitor, a resistor, a memory cell, a processor, and/or the like. In one embodiment, the semiconductor device 615 comprises a back end of line (BEOL) stack. The semiconductor device 615 may comprise a test circuit 210 of stress sensing system 110.

The stress sensing system 110 may determine a distance between a first layer and a second layer of one or more semiconductor device(s) 615. The stress sensing system 110 may be configured to provide an indicator of the determined distance to a process modeling unit 640. The process modeling unit 640 may then compare the determined distance to a specified distance, wherein the specified distance relates to a distance between the first layer and the second layer that is desired for the semiconductor device. The result of the comparison may include a determination that the determined distance is substantially different from the specified distance. For example, the process modeling unit 640 may determine that the determined distance is substantially different if it differs by at least ±5%, ±4%, ±3%, ±2%, ±1%, ±0.75%, ±0.5%, ±0.25%, or ±0.1% from the specified distance, among other values. The process modeling unit 640 may provide an indication of a substantial difference to a process modification unit 630. The process modeling unit 640 may also determine one or more changes to one or more parameters of the instruction set that, if made and implemented, would eliminate the substantial difference between the determined distance and the specified distance.

The process modification unit 630 may modify at least one parameter of the instruction set if the distance is substantially different from the specified distance. By doing so, the process modification unit 630 may generate a modified instruction set. The modified parameter(s) and/or the modified instruction set may be stored in a volatile memory, written to a re-writable memory, or the like. The process modification unit 630 may provide the modified instruction set to the process controller 620, which may then provide the modified instruction set to the semiconductor device manufacturing system 610 for manufacture of subsequent iterations of the semiconductor device.

The system 600 may be capable of performing analysis and manufacturing of various products involving various technologies. For example, the system 600 may produce devices of CMOS technology, Flash technology, BiCMOS technology, power devices, memory devices (e.g., DRAM devices), NAND memory devices, and/or various other semiconductor technologies.

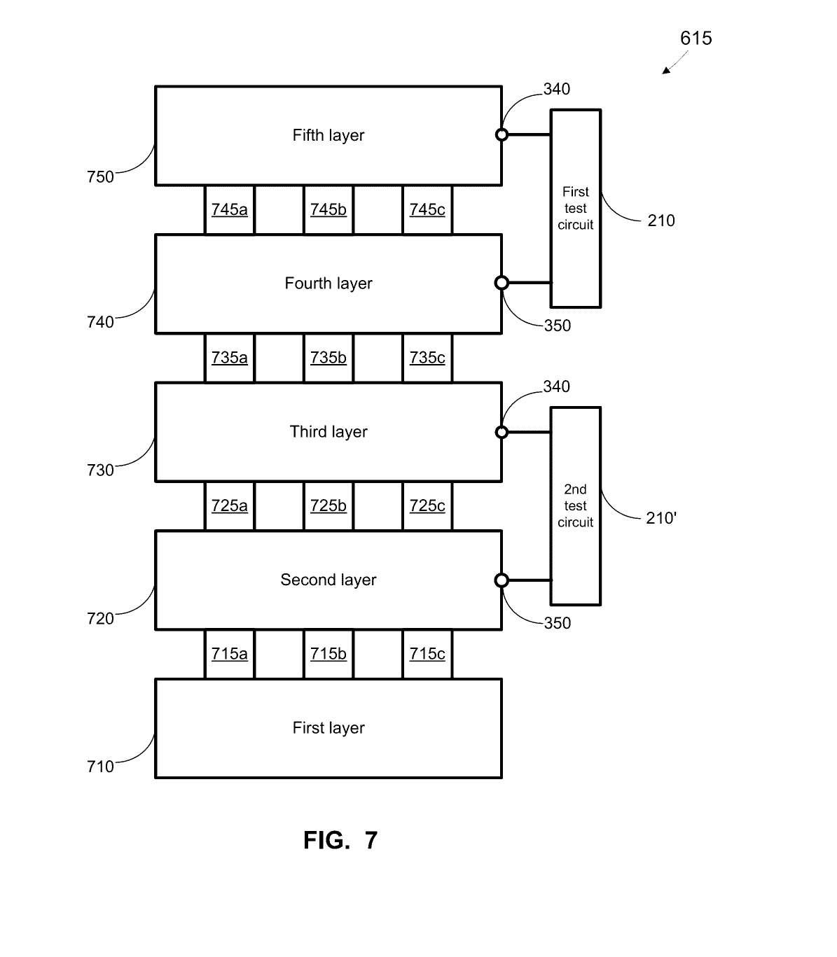

Various embodiments of placement of a test circuit 210C in various semiconductor devices 615 in accordance with embodiments herein are depicted in FIGS. 7-9. FIG. 7 stylistically depicts a semiconductor device 615 comprising a first layer through a fifth layer, 710, 720, 730, 740, and 750. Each pair of adjacent layers may be electrically connected by interconnects 715a-c, 725a-c, 735a-c, and 745a-c. Each of the layers 710-750 comprises at least one layer circuit (not shown). A test circuit 210 comprising first terminal 340 and second terminal 350, each electrically connected to a layer circuit, may be used to measure a distance between any two of layers 710-750. The layers may, but need not, be adjacent. Exemplary test circuit 210 is depicted such that a distance between layers 740 and 750 may be determined. Another exemplary test circuit 210′ is depicted such that a distance between layers 720 and 730 may be determined.

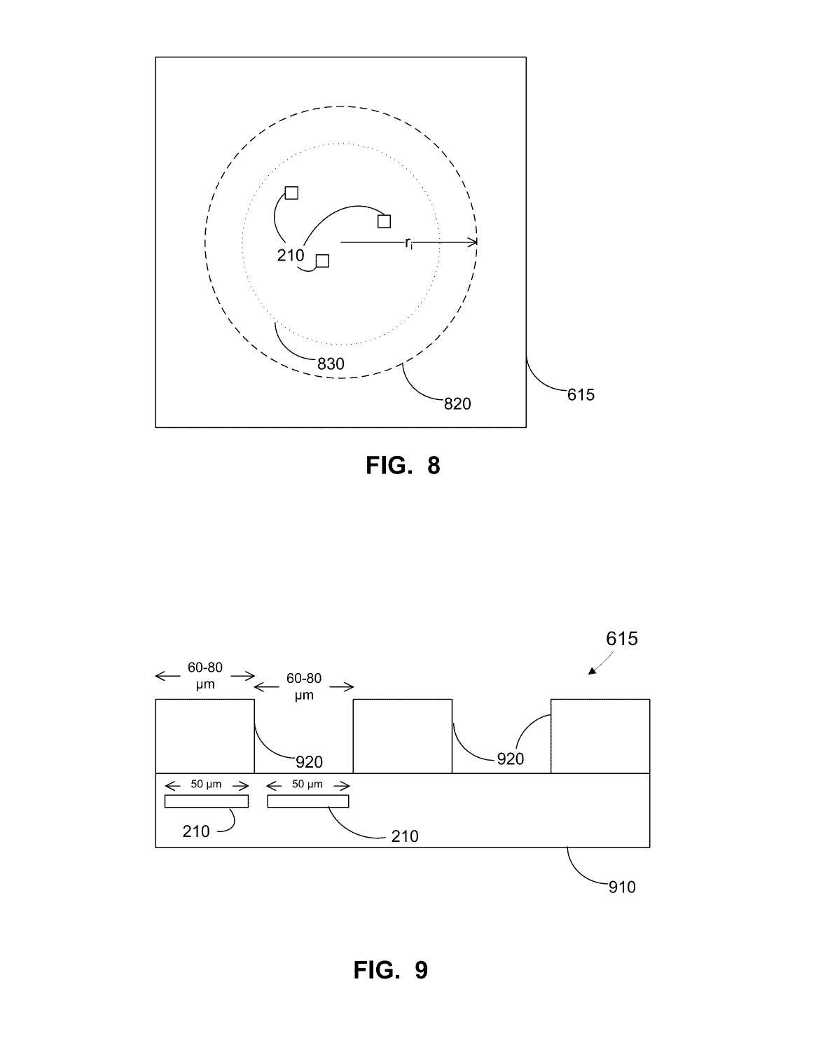

FIG. 8 stylistically depicts a semiconductor device 615, wherein the device 615 is a die having an inscribe radius rᵢ defining an inscribe circle 820. In subsequent processing, integrated circuits or other semiconductor devices are generally fabricated from those portions of the die located within the inscribe circle. One or more test circuits 210 may be located within a second circle 830 having a radius less than the inscribe circle. In one embodiment, the second circle has a radius equal to or less than about 0.7 times the inscribe radius rᵢ from the center of the inscribe circle 820.

FIG. 9 stylistically depicts a semiconductor device 615 having a main body 910 comprising two or more layers (not shown) and one or more features 920 extending vertically from an uppermost layer of the semiconductor device. Typically, features 920 have a width from about 60 μm to about 80 μm and a pitch between features from about 60 μm to about 80 μm. A test circuit 210 may have a width equal to or less than about 50 μm. In one embodiment, a test circuit 210 may be located under at least one of the one or more features. In another embodiment, a test circuit 210 may be located between two of the two or more features. In yet another embodiment, a test circuit 210 may be located partially under one feature and partially between that feature and another feature (not shown).

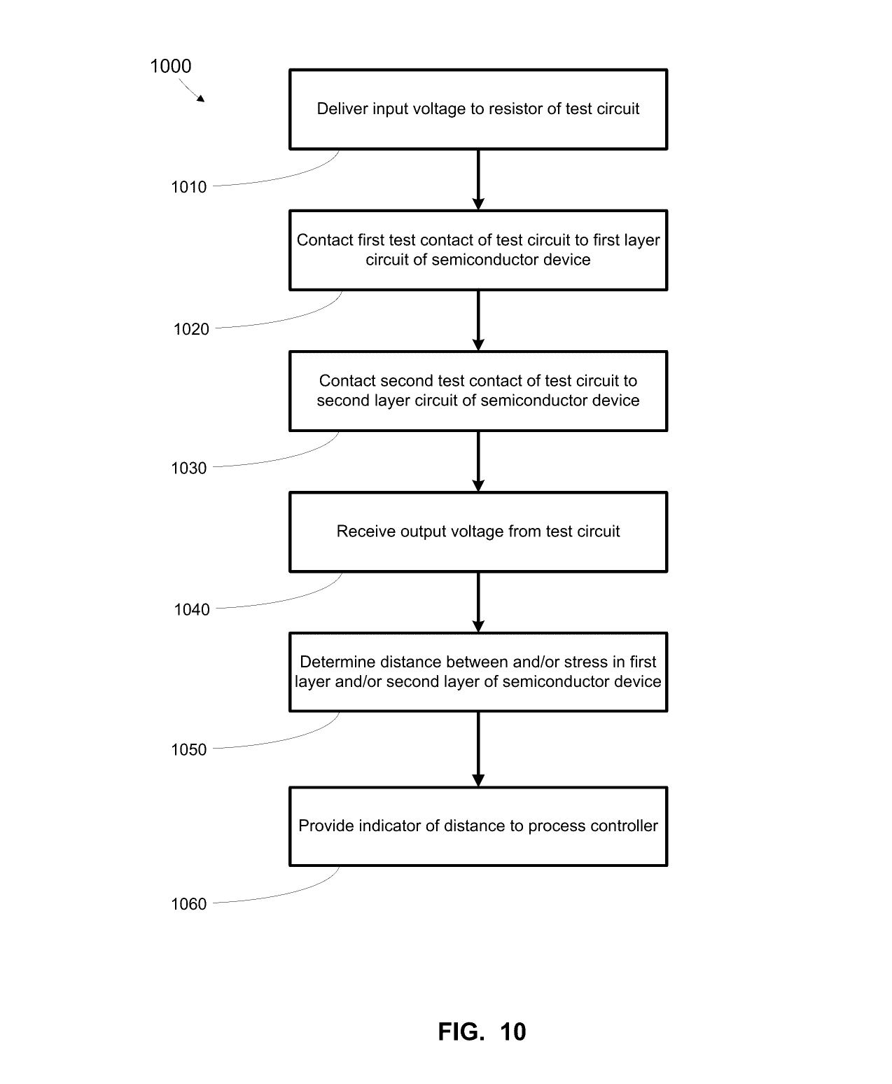

Turning to FIG. 10, a flowchart of a method 1000 in accordance with embodiments herein is depicted. The method 1000 comprises delivering (at 1010) an input voltage (Vᵢₙ) to a resistor 310 of a test circuit 210. In one embodiment, the test circuit (e.g., 210C) comprises the resistor 310 in series with an inductor 320 and a capacitor 330, and the inductor 320 and the capacitor 330 are in parallel. In other embodiments, the test circuit (e.g., 210A or 210B) may comprise only a capacitor 330 or an inductor 320.

The method 1000 also comprises contacting (at 1020) a first terminal 340 of the test circuit 210 to a first layer circuit of a semiconductor device 615, wherein the first terminal 340 is in series with the inductor 320 and/or the capacitor 330, and the first layer circuit is located in a first layer (e.g., 750). Similarly, the method 1000 comprises contacting (at 1030) a second terminal 350 of the test circuit to a second layer circuit of the semiconductor device 615, wherein the second terminal 350 is in series with the inductor 320 and/or the capacitor 330, and the second layer circuit is located in a second layer (e.g., 740).

The method 1000 further comprises receiving (at 1040) an output voltage (Vₒᵤₜ) from the test circuit 210. Based on Vₒᵤₜ and Vᵢₙ, the method 1000 additionally comprises determining (at 1050) a distance between the first layer (e.g., 750) and the second layer (e.g., 740) and/or a stress in at least one the first layer and the second layer.

The method 1000 may further comprise providing (at 1060) an indicator of the distance to a process controller 620 configured to manufacture a second iteration of the semiconductor device 615.

The methods described above may be governed by instructions that are stored in a non-transitory computer readable storage medium and that are executed by, e.g., a processor in a computing device. Each of the operations described herein (e.g., FIGS. 6 and 10) may correspond to instructions stored in a non-transitory computer memory or computer readable storage medium. In various embodiments, the non-transitory computer readable storage medium includes a magnetic or optical disk storage device, solid state storage devices such as flash memory, or other non-volatile memory device or devices. The computer readable instructions stored on the non-transitory computer readable storage medium may be in source code, assembly language code, object code, or other instruction format that is interpreted and/or executable by one or more processors.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

What is claimed is:

1. A method, comprising:
providing an input voltage (Vᵢₙ) to a resistor of a test circuit, wherein the test circuit comprises the resistor in series with an impedance unit, and the test circuit comprises a first terminal in contact with a first layer circuit of a semiconductor device and a second terminal in contact with a second layer circuit of the semiconductor device;
receiving an output voltage (Vₒᵤₜ) from the test circuit; and
determining at least one of a distance between the first layer and the second layer or a stress in at least one of the first layer and the second layer, based on Vₒᵤₜ and Vᵢₙ.

2. The method of claim 1, wherein the resistor has a resistance from about 50Ω to about 250Ω.

3. The method of claim 1, wherein the impedance portion comprises an inductor and a capacitor.

4. The method of claim 3, wherein the inductor has a metal width equal to or less than about 500 nm.

5. The method of claim 1, further comprising providing an indicator of the distance to a process controller configured to manufacture a second iteration of the semiconductor device.

6. A semiconductor device, comprising:
a first layer comprising a first layer circuit;
a second layer comprising a second layer circuit; and
a test circuit, comprising:
a resistor and an impedance unit, wherein the resistor is in series with the impedance unit;
a first terminal electrically connected to the first layer circuit;
a second terminal electrically connected to the second layer circuit;
a voltage input node electrically connected to the resistor; and
a voltage output node.

7. The semiconductor device of claim 6, wherein the resistor has a resistance from about 50Ω to about 250Ω.

8. The semiconductor device of claim 6, wherein the impedance portion comprises an inductor and a capacitor.

9. The semiconductor device of claim 8, wherein the inductor has a metal width equal to or less than about 500 nm.

10. The semiconductor device of claim 6, wherein the test circuit has a width equal to or less than about 50 μm.

11. The semiconductor device of claim 6, wherein first layer and the second layer are adjacent.

12. The semiconductor device of claim 6, further comprising one or more features extending vertically from an uppermost layer of the semiconductor device, wherein the test circuit is located under at least one of the one or more features.

13. The semiconductor device of claim 6, further comprising two or more features extending vertically from an uppermost layer of the semiconductor device, wherein the test circuit is located between two of the two or more features.

14. The semiconductor device of claim 6, wherein the semiconductor device is a die having an inscribe radius defining an inscribe circle, wherein the test circuit is located equal to or less than about 0.7 times the inscribe radius from the center of the inscribe circle.

15. A system, comprising:
a test circuit, comprising:
a resistor and an impedance portion, wherein the resistor is in series with the impedance portion;
a first terminal electrically connected to a first layer circuit in a first layer of a semiconductor device;
a second terminal electrically connected to a second layer circuit in a second layer of the semiconductor device;
a voltage input node electrically connected to the resistor; and
a voltage output node;
an interface configured to receive a directive to sense a stress and deliver an input voltage (Vᵢₙ) to the voltage input node of the test circuit in response to the directive; and
a stress data unit, configured to receive an output voltage (Vₒᵤₜ) from the voltage output of the test circuit and determine at least one of a distance between the first layer and the second layer or a stress of at least one of the first layer and the second layer, based on Vₒᵤₜ and Vᵢₙ.

16. The system of claim 15, wherein the resistor has a resistance from about 50Ω to about 250Ω.

17. The system of claim 15, wherein the impedance portion comprises an inductor and a capacitor.

18. The system of claim 17, wherein the inductor has a metal width equal to or less than about 500 nm.

19. The system of claim 15, wherein the test circuit has a width equal to or less than about 50 μm.

20. The system of claim 15, further comprising:
a process controller, configured to provide an instruction set comprising a plurality of parameters for manufacture of the semiconductor device to a manufacturing system;
the manufacturing system, configured to manufacture the semiconductor device according to the instruction set;
a process modeling unit, configured to receive the distance between the first layer and the second layer from the stress data unit and compare the distance to a specified distance;
a process modification unit, configured to modify at least one parameter of the instruction set if the distance is substantially different from the specified distance, yielding a modified instruction set, and provide the modified instruction set to the process controller;
wherein the process controller is further configured to provide the modified instruction set to the manufacturing unit for manufacture of a subsequent iteration of the semiconductor device.
